(19) United States
(12) Patent Application Publication
(10) Pub. No.: US 2006/0248417 A1
(43) Pub. Date: Nov. 2, 2006

(54) CLOCK CONTROL CIRCUIT FOR TEST THAT FACILITATES AN AT SPEED STRUCTURAL TEST

(75) Inventors: Henry R. Farmer, Colchester, VT (US); Gary D. Grise, Colchester, VT (US); David W. Milton, Underhill, VT (US); Steven F. Oakland, Colchester, VT (US); Mark R. Taylor, Essex Junction, VT (US)

Correspondence Address: IBM MICROELECTRONICS;INTELLECTUAL PROPERTY LAW, 1000 RIVER STREET, 972 E, ESSEX JUNCTION, VT, 05452, US

(73) Assignee: INTERNATIONAL BUSINESS MACHINES CORPORATION, Armonk, NY (US)

(21) Appl. No.: 10/908,123

(22) Filed: Apr. 28, 2005

(51) Int. Cl. G01R 31/28

(52) U.S. Cl. 714/724

(57) ABSTRACT

A clock selection circuit selectively passes one or more clocks into portions of an integrated circuit for testing. In one mode, the selection circuit passes a functional clock into a section of logic for an at speed test under test program control. In another mode, the selection circuit passes a clock other than the functional clock, such at a reduced frequency, in a test mode.

### TECHNICAL FIELD

The field of the invention is that of testing integrated circuits, in particular testing logic circuits structurally using clock signals that are operated at functional speed.

### BACKGROUND OF THE INVENTION

In the standard methods of testing ASIC integrated circuits, the circuit contains test structures that supply a scan vector to the operating components, which process that data. The result of the processing of the scan vector is then compared against the expected values to see if the part passes or fails.

In addition, to supplying a scan vector of data for the circuit to operate on, the testing setup also supplies a set of clock signals. In various test modes, non-standard clock pulses may be required. The required clock signal may be a short pulse train, a single pulse, a single edge of a clock pulse (rising or falling) or a DC level, high or low.

Integrated circuits often have different clock domains that use clock signals that may differ in phase and/or frequency. The invention enables an at speed structural test of logic using the functional clock. The invention does not depend on a particular scan style such as Mux-Scan or LSSD.

FIG. 1 shows a simplified block diagram of a test setup, in which there is a clock input which is capable of producing a train of pulses that are output as the primary clock 350 for the logic under test 370. Block 100 represents a circuit according to the invention, in which the primary clock is either passed to or blocked from the section of the circuit being tested. Alternatively, a different clock for the purposes of the test may be substituted as illustrated in the second half of the diagram. There are 2 clock inputs each of which is capable of producing a train of clock pulses. A clock in question is selected and passes out of line 350 into block 370. Block 370 represents the portion of the circuit being tested, together with scan latches for storing control data or test data and the logic being tested.

FIG. 2 shows a parent domain 210 that is fed by a parent clock 201. The child domain may be fed by the output of circuit 200 for test purposes. Circuit 200 according to the invention passes on a selected clock signal to a child domain 220. Optionally, a different clock or more than one clock may be passed to an overlapping domain 220. Thus, the testing system has the option of testing all the logic, parent domain and child domains, with the functional clock 201, or blocking the functional clock 202 (or the test clock) from the child domain part of the circuit.

In typical design practices, the components of the clock distribution signals for test clocks are not as fast as the comparable distribution system for functional (those used in normal operation) clocks, so that it is not possible to perform an “at speed” test; i.e. at normal operating speed. Evidently, there may be a problem in a circuit that operates correctly at a reduced test speed, but not at the nominal operating speed.

For typical structural test of an integrated circuit, a slow test clock is brought in and replaces the functional clocks. This clock is slow enough that all the logic in multiple clock domains can be tested using this single clock. In addition functional clock manipulation circuits such as clock selection, phase shifting, and clock gating can be bypassed and ignored. As the test clock speed is increased towards the functional clock speeds problems appear with the clock manipulation circuits rendering the tests invalid.

The art could use a flexible system for performing a test at the functional speed. In addition the art could use a flexible system for testing using clocks approaching or at functional clock speeds. This system should be able to correctly handle commonly used clock manipulation circuits. The invention enables a method of testing correctly such clock manipulation circuits.

### SUMMARY OF THE INVENTION

The invention relates to a clock selection circuit for selectively passing one or more clocks into portions of an integrated circuit for testing.

A feature of the invention is that the selection circuit contains stored data for selecting which clock is to be passed or blocked into a domain of the circuit for test.

Another feature of the invention is the ability to pass a functional clock into a section of logic for an at speed test under test program control.

Another feature of the invention is the ability to pass a clock other than the functional clock into the logic in a test mode.

### BRIEF DESCRIPTION OF THE DRAWINGS

FIG. 1 shows an overall block diagram of an integrated circuit under test with a clock gating or with a clock selection circuit.

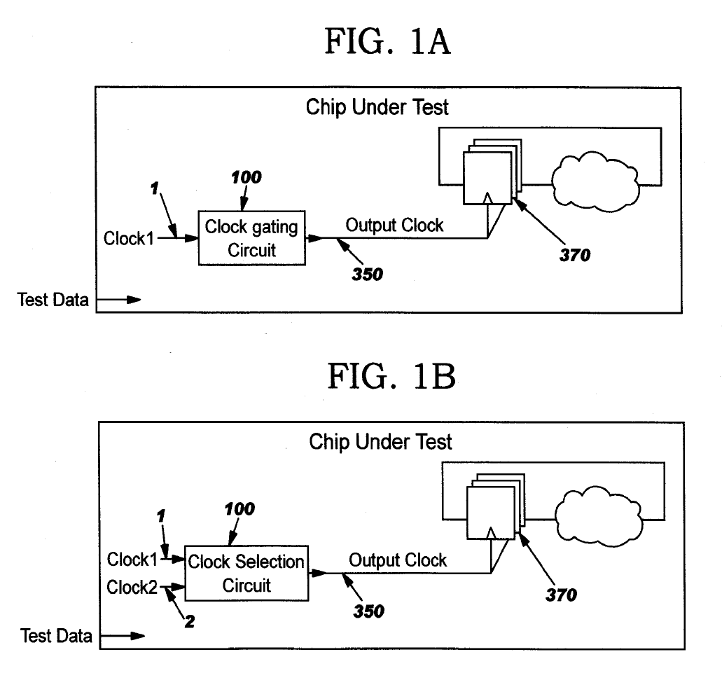

FIG. 2 shows a block diagram of a parent domain coupled to a child domain.

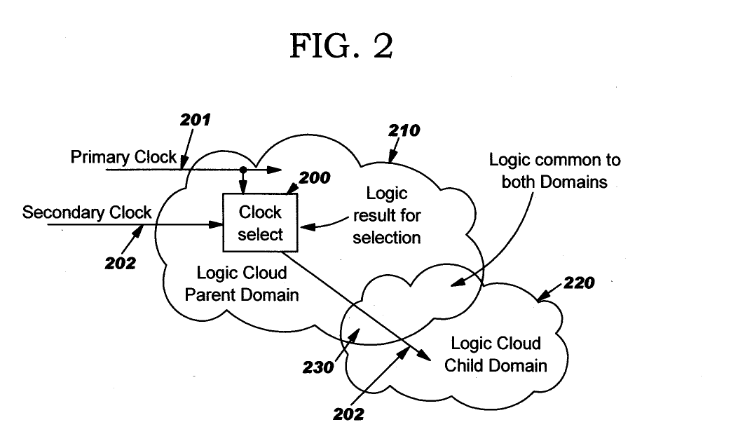

FIG. 3 shows a prior art circuit that may be used with the invention to provide selectable phase shifting of a functional clock.

FIG. 4 shows a flow chart illustrating available options.

FIG. 5 shows a first embodiment of the invention for clock gating.

FIG. 6 shows a second embodiment of the invention for clock selection.

### DETAILED DESCRIPTION

When testing an ASIC using functional clocks, additional control of clock structures are needed to permit selection of the necessary clock configuration in a multiclock domain environment. A key element of control involves clock gating.

Clock gating is a structure often used by designers for power control, clock selection, etc. In traditional stuck fault testing, this control is not a problem as the design is flattened to a single clock domain and the test clock timing is very slow compared to the functional clock operation. When a design is to be tested using clocks at functional speeds, test vectors are scanned in using the slow test clock and then the design is un-flattened for test and clocks at functional speeds are used for a highly parallel but non-functional test. Not having clock gating controllable under test can lead to low coverage when the clock gating is not enabled (clock passed through) or the wrong gate is enabled often causing the logic behind the clock gate not to be tested adequately. Also not having clock gating controllable under test can lead to test failures where mutually exclusive clock gates were enabled in a design employing tradition hard wired clock gating for test.

When testing an ASIC using functional clocks, additional control of clock structures are needed to permit selection of the necessary clock configuration or modification of clock operation in a multilink domain environment. A key element of such control involves basic clock selection.

Clock selection is a structure often used by designers to select between different clock frequencies or clock phases, etc. In traditional stuck fault testing, this control is not a problem as the design is flattened to a single clock domain and timing is very slow compared to the functional clock operation. When a design is to be tested using clocks at functional speeds, test vectors are scanned in using the slow test clock and then the design is un-flattened for test and clocks at functional speeds are used for a highly parallel but non-functional test. Not having clock selection controllable under test can lead to low coverage when the clock selection is not enabled for the fastest or most demanding clock causing the logic behind the clock selection not to be tested adequately. Also not having clock selection controllable under test can lead to test failures where mutually exclusive clock selections are enabled. When the test vectors are being generated for targeted faults, the software can work to overcome these difficulties with increased test generation time and larger test vector volume. However when there have been no structural provisions to fix mutually exclusive clock selections, no such solutions exist. The structure described below overcomes these obstacles. This proposal is independent of test style (LSSD or Mux-Scan).

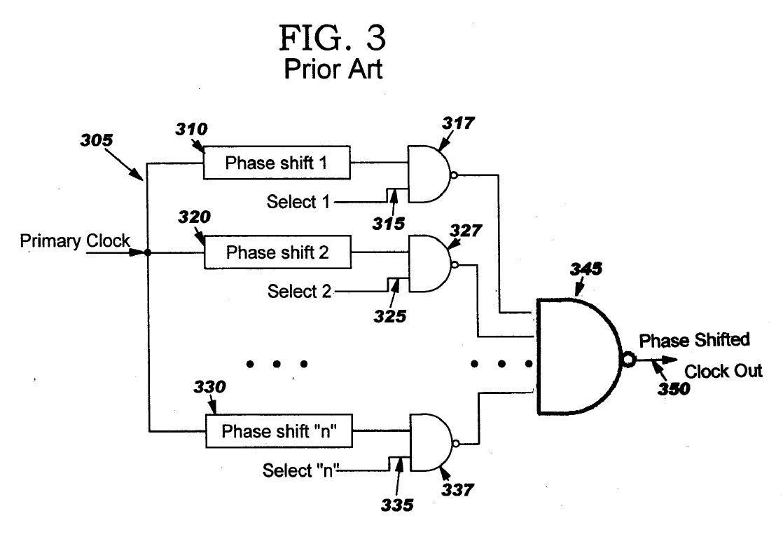

FIG. 3 illustrates a prior art circuit to which this invention may be applied. This circuit selectively shifts the phase of a clock and is a commonly used circuit to match an internal clock to incoming data. There can be a number n of possible phase shifts. A ‘one of n’ decoder logic would select the appropriate phase shift for incoming data to achieve the highest reliable data transfer to the functional application.

According to the present invention, to achieve testability objectives, it is required to be able to selectively enable or disable a clock gate. If all clock gating was enabled, (the clock is allowed to propagate through the circuit), then the sum of the phase shifts would result in a clock output which would be unacceptable for an at speed functional test. If all the clock gates were turned off (clock not allowed to propagate through) then the logic that is activated or exposed by this clock circuit would not be testable, resulting in a loss of coverage. This invention allows a method of control to permit test ability and coverage.

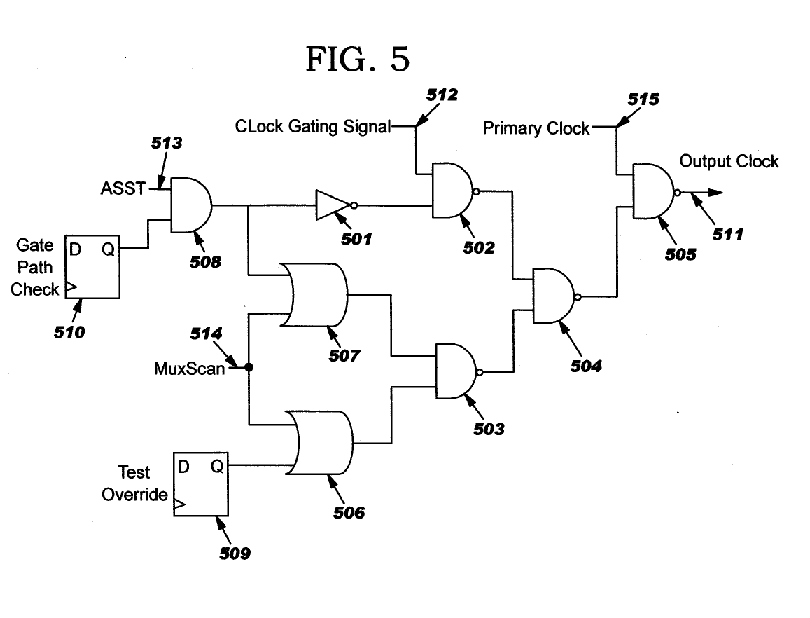

Clock gates such as 317, 327 and 337 would be handled by the following method. First, during functional synthesis or during Design For Test Synthesis (DFTS), Clock gates such as 317, 327 and 337 would be replaced by the invention as illustrated by FIG. 5. The ‘Phase shift n’ outputs, where n would represent 1 through n possible phase shifts circuits 310, 320, and 330, would be tied to the respective Primary Clock pin of the invention for each clock gate which is replaced by DFTS. The ‘Select n’ pin, where n would represent 1 through n gate enables would be tied to the respective Clock Gating Signal of the invention for each substitution. Two test control signals are provided for testing that are the ASST (At Speed Structural Test) signal, which is a signal that is normally low for functional use and structural stuck at fault testing and is high when a high speed functional or test clock is to be used for test; and the MuxScan Control signal which is a signal used to select all clock gates when a test clock is used which is slow enough that the various phase shifts are no longer a problem. When the MuxScan Control signal is high, a slow test clock can be propagated to all the logic under test to permit the scanning of the test vector. The structure after DFTS is now under test program control to select which is the most appropriate shifted clock for test, the rest of the phase shifted outputs can be blocked. In addition, if it were desired to test the selection logic, the structure can be programmed to permit this test to occur.

The following circuit shown in FIG. 5 allows the controllability desired for clock gating. It can be used in its entirety or in part as needs dictate. Clock gating would be accomplished in a design by the use of a NAND 505 with one input pin being the primary clock and the other input pin a Clock Gating Signal that comes from the clock gating control circuit. After DFTS, the ‘Clock Gating signal’ is replaced with a new logic structure and the ‘Clock Gating Signal’ is connected into the new logic structure. The original clock gating NAND 505 could also equally be an AND, an OR, or a NOR logic gate depending on the functional clock gating requirement. The invention works for any type of clock gating.

Here Gate 505 is the customer's gating logic. Logic gates 501-504 and 506-510 are the added logic to provide tester control. The ASST signal is low for functional usage as well as for Stuck At Fault testing. When switching modes to an At Speed Structural Test, the ASST signal would go high after scan is completed (or earlier). This transfers the gate control from the ASIC designer's logic to tester control. The Flip-Flops 509 & 510 then select how clock gating is to be handled. These flip-flops are either part of the general scan chains or could be special test control registers (advantageous for LBIST).

For normal operation, (mission mode) the ASST signal and MUXSCAN signals are low. This removes AND 508, Inverter 501, OR 507 and NAND 503 from control. The ‘Clock Gating signal’ 512 passes through NAND 502 and NAND 504 and is applied in its true state to NAND 505. The other inputs to NANDS 502 and NAND 504 have been forced high by the control signals 513 and 514 being low.

For test purposes, the method of operation needs to be broken into two modes of operation. The first is the SCAN load of the scan latches. The second is the At Speed Test of the logic.

For scan load of scannable latches in a MuxScan environment, the MuxScan signal (this could be the SE Scan Enable typically used or a unique signal as a design dictates) goes high forcing the input to clock gate NAND 505 allowing the clock 515 to propagate through to output 511. When MuxScan signal 514 is high, the state of the ASST signal 513 is a don't care. The MuxScan signal input into OR gate 507 and OR gate 506 forces both inputs of NAND 503 high in turn forces one input of NAND 504 low. With one input of NAND 504 low, its output goes high allowing the clock to propagate through NAND 505. The scan flip-flops of the design as well as flip-flops 510 and 509 are loaded with the appropriate test values. In a LSSD environment, the MuxScan control signal is not required and could be omitted, OR 507 and OR 506 are removed and the Test Override Flip-flop 509 being directly wired to NAND 503.

For the At Speed Test, the MuxScan Control signal 514 goes low, the ASST signal 513 goes high and the operation is now dependent on the state of the ASST signal and the contents of the scan flip-flop 509 and 510 which determine the desired mode during test.

If the clock gating signal path is to be tested, the Gate Path Check flip-flop 510 is loaded with a “0” and the circuit behaves as it would in a functional mode. The “0” on input of AND 508 forces its output low which in turn forces inputs to NAND 502 and NAND 504 high. This allows the Clock Gating Signal 512 to propagate through to the input of NAND 505. The contents of the Test override flip-flop 509 is a don't care. If it is not desired to test the clock gate generation logic, the flip-flop 510 and NAND 508 can be omitted and the ASST control signal 513 can go directly to INVERTER 501.

If the state of the clock gate is to be changed by test control, then the Gate Path Check flip-flop 510 is loaded with a “1” that combined with ASST control signal 513 being high forces the input to NAND 502 low and removes control of Clock Gating Signal from NAND 502. The contents of the Test Override flip-flop determine the operation of the clock gate NAND 505. If the Test Override flip-flop 509 is loaded with a 1, the input to NAND 505 is forced high and the clock gate NAND 505 is enabled (the clock is passed through). If the Test Override flip-flop is loaded with a 0, the input to NAND 505 is forced low and the clock gate NAND 505 is disabled (the clock is blocked from propagating through).

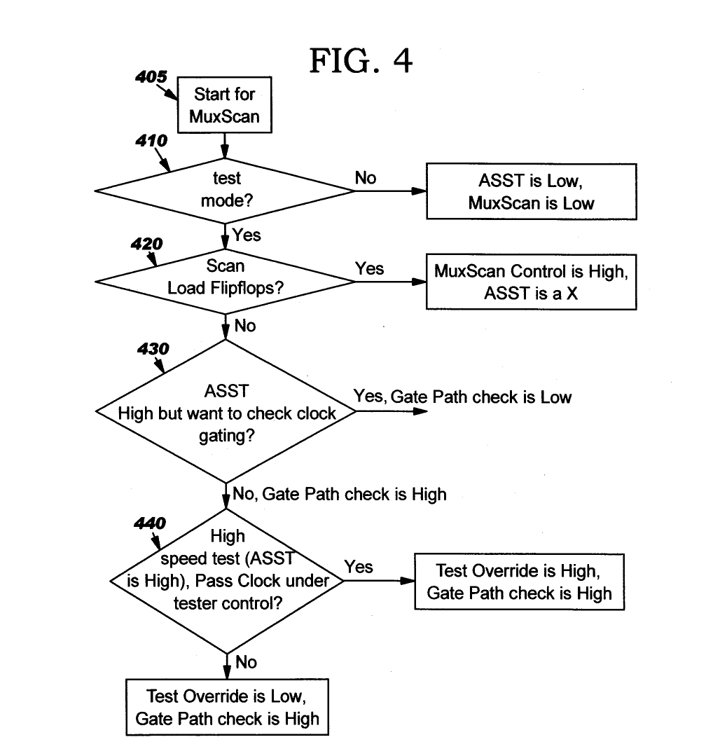

The flow chart in FIG. 4 describes this method as applied to a test mode of tester control of the clock gate:

The process starts in block 405, then the first decision point is in block 410. If ASST is low and MuxScan is low, then the normal test or high speed test modes are not operative and the circuit behaves functionally.

The second decision point is block 420. When it is desired to scan data for testing, the MuxScan control is high and the ASST control signal is a don't care. and then all the clock gates are forced on (clocks propagated through). This allows the scan of scannable flip-flops and a test vector can be loaded.

The third decision point 430 is during the ASST test mode (ASST is high). Here a decision is made if the Gating logic is to be tested. If the test is desired, then the Gate Path Check flip-flop is loaded with a “0” and the ASST signal is invalidated and the circuit performs functionally.

The fourth Decision point is block 440. Here the propagation of the clock is under tester control, the ASST signal is high and the Gate Path Check Flip-flop is a one. The output of the Test Overide flip-flop controls the clock gate.

If the clock is blocked functionally then the logic fed by the clock is inactivated or that path for clock manipulation is not selected. If the path is blocked under test then the logic fed by the clock is not tested (intentionally) or that path for clock manipulation is not selected. It could be that a different path is selected.

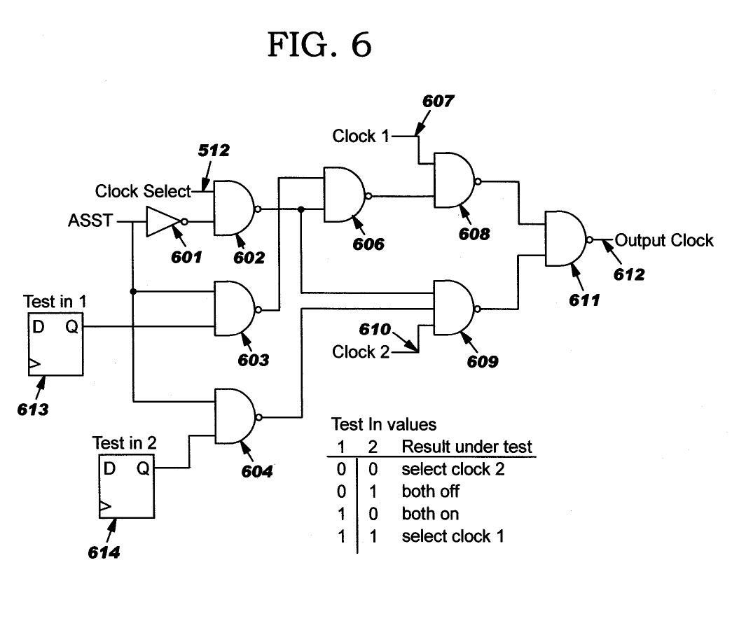

FIG. 6 illustrates a different circuit having a common design structure which could be used for a case where clock selection is done (there are 2 clock gates, one of which is always enabled). This allows a reduction of logic gates. However, FIG. 5 could achieve the same logic function but the clock select signal would go to one and the inverted clock select would go to the other.

FIG. 6 shows an alternative embodiment that does not use the MuxScan feature but would be used where one of 2 clocks would be selected. This is a common design structure. This same function could be accomplished by using 2 of the circuits in FIG. 5 with the clock select signal going to one and the inverted clock select would go to the other. However using 2 of the FIG. 5 circuits results in more gates. For FIG. 6, Gates 608, 609 and 611 are the customer's selection logic. Elements 601-604, and 606, 613 and 614 are the logic added in DFTS to provide tester control. The ASST signal is low for functional usage as well as for Stuck At Fault testing. When switching modes to an At Speed Structural Test, this signal would go high after scan is completed (though could be high earlier). This transfers the gate control from the ASIC designer's logic to tester control. The Flip-Flops 613 and 614 then select how clock selection is to be handled. These flip-flops are either part of the general scan chains or could be special test control registers (advantageous for LBIST). Flip-Flop 613 allows forcing the clock selection for Clock 1. Flip-Flop 614 allows forcing the clock selection for Clock 2. The use of two Flip-Flops allow for neither or both clocks to be selected. If this additional control is not needed, then Flip-Flop 614 could be eliminated and Flip-Flop 613's output would go to both NAND 603 and NAND 604. The gates 602, 603, and 604 are shown as NANDS as this typically has the least delay impact but they could also be done as ANDS and an OR if desired. If it is desired to have a MuxScan enabled circuit, then additional logic under MuxScan control could be added to force the outputs of the flip-flops 613, 614 to either “0”s or “1”s.

The preceding discussion has used terms for various control signals that are common in the art. Other designers, however, may use different terms for a signal performing the same function. For purposes of the following claims, the signal referred to by the abbreviation ASST will be referred to as the first test control signal; the signal referred to as MuxScan will be referred to as the second test control signal; and the signal referred to as the Clock Gating Signal will be referred to as the third test control signal.

While the invention has been described in terms of a single preferred embodiment, those skilled in the art will recognize that the invention can be practiced in various versions within the spirit and scope of the following claims.

What is claimed is:

1. A clock gate control circuit to enable functional test of an integrated circuit, comprising:
a test control logic network coupled to a clock gate of the integrated circuit for controllably blocking the passage of a primary clock;
a first test control signal ASST within the test control logic corresponding to an at speed structural test mode that blocks a primary clock signal from passing through the clock gate;
a second test control signal (MuxScan) within the test control logic corresponding to a mux scan test mode that passes the primary clock through the clock gate;
a third test control signal (Clock Gating Signal) within the test control logic corresponding to a clock gating signal that enables the clock gate;
a first latch to store a value used to enable switching of control of the clock gate from an external tester to an internal logic function; and
a second latch to store a value used to override a test mode.

2. A circuit according to claim 1, adapted for a mux scan test mode, in which the second test control signal is high and said first test control signal is low.

3. A circuit according to claim 2, in which said third test control signal is suppressed; and
said first test control signal is suppressed, whereby a path is opened that permits stored data to pass through said clock gate.

4. A circuit according to claim 1, adapted for a test of a clock gating path, in which the first test control signal is high and stored data in the first latch is low.

5. A circuit according to claim 4, in which said first test control signal suppresses the contents of said second latch.

6. A circuit according to claim 1, adapted for controllable propagation of the clock, in which the first test control signal is high, the first latch is high, the second latch is low.

7. A circuit according to claim 6, in which control of said clock gate is suppressed, passing the clock under control of the contents of said second latch.

8. A circuit for clock gating in an integrated circuit comprising:
a controllable logic test network for passing a selected one of at least two clock signals through a clock gate, said at least two clock signals comprising a functional clock for use in normal operation and at least one test clock;
selection logic for providing tester control of at least one of said at least two clock signals; in which
first control logic blocks a primary clock signal from passing through the clock gate in an at speed test mode and passes said primary clock in a second test mode;
second control logic enables the clock gate and passes a clock signal specified by stored data;
stored data controls third test logic to control the clock gate in the at sped test mode.

9. A circuit according to claim 8, in which said primary clock signal passes through said clock gate under control of a first test control signal and stored test data within said circuit are processed at speed.

10. A circuit according to claim 9, in which the contents of stored data determine the mode of said test.

11. A circuit according to claim 8, in which said primary clock signal is blocked from passing through said clock gate in said second test mode and a clock signal specified by stored data tests the clock gating signal path.

12. A circuit according to claim 11, in which said first test control signal is high and said first stored data is low.

13. A circuit according to claim 8, in which said primary clock signal is blocked from passing through said clock gate in said second test mode and a clock signal specified by stored data passes through said clock gate as specified by stored test override data.

14. A circuit according to claim 6, in which control of said clock gate is suppressed, passing the clock under control of the contents of said second latch.

15. A circuit for clock gating in an integrated circuit comprising:
a controllable logic test network for passing a selected one of at least two clock signals through a clock gate, said at least two clock signals comprising a functional clock for use in normal operation and at least one test clock;
selection logic for providing tester control of at least one of said at least two clock signals; in which
first control logic selects one of two clock signals; and
second control logic enables the clock gate and passes a clock signal specified by stored data, in which control shift logic switches control from said integrated circuit to test control; and
stored data controls which of two clocks is selected.

16. A circuit according to claim 5, in which data in a first data storage element forces the selection of a first clock and data in a second storage element forces selection of a second clock.
